(19) United States
(12) Patent Application Publication
(10) Pub. No.: US 2026/0247526 A1
(43) Pub. Date: Aug. 20, 2026

(54) DEFORMABLE ARTICLE

(71) Applicant: SENDANCE GMBH, Linz (AT)

(72) Inventor: Robert KOEPPE, Linz (AT)

(73) Assignee: SENDANCE GMBH, Linz (AT)

(21) Appl. No.: 19/165,644

(22) PCT Filed: Mar. 12, 2024
(86) PCT No.: PCT/AT2024/060085

§ 371 Date: Sep. 16, 2025

(30) Foreign Application Priority Data
Mar. 23, 2023 (AT) A50219/2023

(51) Int. Cl. H05K 1/02

(52) U.S. Cl. CPC H05K 1/0283

(57) ABSTRACT

An object including a body, wherein at least one circuit board and conductor paths connected thereto are present on at least one surface of the body, wherein the body is deformable and at least the surface of the body is porous, wherein the conductor paths are stretchable and wherein at least the conductor paths are covered by an elastomer, wherein the elastomer extends into the pores of the surface of the body.

### CROSS-REFERENCE TO RELATED APPLICATIONS

The present application is a national phase application of PCT Application No. PCT/AT2024/060085, filed Mar. 12, 2024, entitled “DEFORMABLE ARTICLE”, which claims the benefit of Austrian Patent Application No. A50219/2023, filed Mar. 23, 2023, each of which is incorporated by reference in its entirety.

### BACKGROUND OF THE INVENTION

### 1. Field of the Invention

The invention relates to a deformable object comprising a body made of deformable and porous material, which is equipped with electronic components.

### SUMMARY OF THE INVENTION

The objective of the invention is to create an object equipped with electronic components, wherein the object is to be deformable, wherein damage to the electronic components or detachment thereof during deformation of the object is to be prevented.

In one embodiment, an object is proposed comprising a body, wherein at least one circuit board and conductor paths connected thereto are present on at least one surface of the body, wherein the body is deformable and at least said surface of the body is porous, wherein the conductor paths are stretchable and wherein at least the conductor paths are covered by an elastomer, wherein the elastomer extends into the pores of the surface of the body.

It is preferred that the elastomer also at least partially covers the circuit board or each of several circuit boards.

It is preferred that the surface of the body on which the conductor paths and the circuit boards are present lies at the bottom of a recess in the body, wherein the recess is completely filled with the elastomer.

In one embodiment, the surface of the body on which the conductor paths and the at least one circuit board are located is completely covered by the elastomer.

In one embodiment, at least one circuit board has an electronic component or a contact surface, wherein a surface of the electronic component or the contact surface is flush with the surface of the elastomer.

In one embodiment, at least one circuit board has an electronic component, wherein in the area of the electronic component, instead of the elastomer, there is a plastic different from the elastomer, which extends to the surface of the elastomer.

It is preferred that the conductor paths are in the form of cables or wires which have a winding, meandering or kinked course.

It is preferred that the body is stretchable and elastic.

In one embodiment, a method for manufacturing an object is proposed, comprising a body which is deformable and has at least one porous surface, wherein
in a first step, at least one circuit board and stretchable conductor paths connected thereto are placed on the porous surface of the body,
wherein in a second step, at least the conductor paths are covered with a first material, which first material penetrates into the pores of the surface of the body and completely covers at least the conductor paths,
wherein in a third step, the first material is cured to form an elastomer.

It is preferred that, in a first step, several circuit boards are placed on the porous surface of the body, which circuit boards are connected at least to each other by the stretchable conductor paths, wherein at least one electronic component is present on each circuit board and wherein, in a second step, the stretchable conductor paths are completely covered and the circuit boards are at least partially covered.

It is preferred that the surface of the body on which the conductor paths and the at least one circuit board are located lies at the bottom of a recess in the body, wherein the body is already originally manufactured with this recess or is provided with this recess before the first step.

It is preferred that, in addition to encapsulation with the first material, encapsulation with a second material takes place, wherein the second material is applied in the area of at least one electronic component present on a circuit board, wherein the second material cures to form a plastic which has different properties to the elastomer.

It is preferred that the casting with the first casting compound is carried out to such an extent that the surface of the elastomer is flush with one or more of the following surfaces:
a surface of the body which is raised relative to the surface of the body on which the conductor paths and the at least one circuit board are present; a surface of a contact area which is raised on a circuit board; a surface of an electronic component that is raised on a circuit board; a surface of a plastic that is formed by molding with a second material in the area of an electronic component on a circuit board.

The material of the body is porous, which means that it has a surface structure into which a casting compound or coating applied in a liquid state can penetrate.

This ensures that the applied layer adheres well to the porous body.

Preferably, the material of the body has pores with an average pore size of at least 25 μm, more preferably at least 100 μm, and in particular at least 250 μm.

The porous body is deformable.

The porous body may be stretchable.

The porous body may be elastic.

The porous body preferably has a flat shape, i.e., a length and width that are each a multiple of the thickness of the body.

The surface on which the electronic components and the stretchable conductor paths are located can be regarded as the plane of the body. The electronic components and the stretchable conductor paths can also be located on a curved surface of the body.

Deformable in this context means deformation of the body transverse to the plane or transverse to the surface on which the electronic components are located. For example, bending or folding the body, or indenting the material of the body. Stretchable means deformability in the longitudinal or transverse direction of the body, which is accompanied by a change in dimensions in the plane of the body, in particular a change in dimensions of the surface on which the electronic components are located. In this context, stretchable refers in particular to a body whose length or width can be extended by a tensile force. Elastic refers to the fact that the body returns to its original dimensions after the tensile force or compressive force is removed.

The material of the body can be, in particular, a textile, an open-pored foam, felt, rough leather, or a 3D-printed lattice structure (three-dimensional grid).

In one embodiment, the invention comprises a body made of a material that is deformable and porous (textile, open-pored foam, felt, rough leather, 3D-printed lattice structure), on the surface of which thin circuit boards with electronic functionalities are present, which are connected by stretchable conductor paths, wherein the thin circuit boards and the stretchable conductor paths are fixed to the surface of the body
by being enclosed in a cured layer of an elastomer (e.g., silicone, polyurethane), wherein a precursor of the elastomer was applied in liquid form and cured on the body,
wherein part of the elastomer has penetrated into the pores of the material of the body, thereby forming a mechanically strong bond.

Sensors, indicators, and/or actuators may be present on the thin circuit boards, whereby one or more of the aforementioned electronic components may be present on each of the individual circuit boards.

In one embodiment, the stretchable conductor paths are in the form of meandering cables.

The stretchable conductor paths may be present without insulating material. The stretchable conductor paths may comprise several individual parallel cables, each of which has its own insulating sheath. Several conductor paths may be present together in an elastic insulating material, which electrically insulates the several electrical conductor paths from each other and preferably also from the outside. However, the electrical conductor paths may also be uninsulated on the surface of a substrate in the form of a stretchable tape. The electrical conductor paths may themselves consist of elastic conductive material. However, the electrical conductor paths may also be arranged in such a way that they can be pulled apart due to a twisted or folded course. The conductor paths may be printed on a stretchable substrate. The conductor paths can be in the form of wires or stranded cables. The conductor paths can be in the form of elastic conductive fibers, for example by winding a metallic wire around an elastic fiber. The conductor paths can each have insulation and be attached to a stretchable substrate.

The elastomer is deformable, stretchable, and elastic.

The elastomer may be, for example, silicone or polyurethane.

The elastomer preferably completely covers the thin circuit boards and the conductor paths.

The material of the conductor paths is preferably a conductive metal, in particular aluminum, copper, silver, or gold, with copper being particularly preferred. In addition, carbon black and conductive polymers can be used.

In one embodiment, sensor surfaces, contact surfaces, display surfaces, display elements, or actuators protrude from the elastomer or are flush with the surface of the elastomer.

The object may be a textile rubber coated by the elastomer, with conductor paths and circuit boards embedded in the rubber coating.

In a preferred embodiment, there are recesses in the surface of the object, into which the circuit boards and stretchable conductor paths are inserted, whereby the recesses are completely filled with a liquid precursor of the elastomer so that the surface is continuous again and the circuit boards and conductor paths are enclosed.

The body can be manufactured with the recesses already in place, e.g. in the case of a 3D-printed body, or the body can be manufactured in a mold, for example by foam extrusion. The recesses can also be carved into the body by means of an additional work step, for example by cutting, milling, or laser ablation.

Preferably, the modulus of elasticity of the body and the elastomer are matched to each other. The deviation between the two moduli of elasticity is preferably less than 10%. In one embodiment, the body and the elastomer have the same modulus of elasticity.

In one embodiment, at least one circuit board contains a pressure sensor, humidity sensor, strain sensor, temperature sensor, chemical sensor, or a combination of several of these sensors.

In one embodiment, at least one circuit board contains an LED, an actuator, or an electrode for sending electrical impulses, or a combination of several of these elements.

In one embodiment, the object is worn on the human body, for example as a garment, insole, or headband. In one embodiment, the object is a cushion, pillow, seat cushion, or mattress.

In one embodiment, at least two different materials are used to cast the components, wherein a first material cures to form an elastomer and a second material is used for casting in the area above at least one circuit board, which second material is different from the first material so that it cures to form a plastic with different properties than the elastomer.

Preferably, a layer of the second material is applied over a sensor of a circuit board instead of the first material of the elastomer, which second material cures to form a plastic that allows better transmission of the sensor's measurement signal. In one embodiment, a second material is applied over a pressure sensor, which cures to form a plastic with a higher hardness than the hardness of the elastomer. In one embodiment, an air-or water-permeable plastic formed from the second material is present over a humidity sensor, pH sensor, or chemical sensor. In the case of a light sensor or a display element such as one or more LEDs, a plastic formed from the second material may be present, which is more transparent than the elastomer.

The elastomer may be opaque.

The elastomer may be transparent or translucent.

The elastomer is preferably impenetrable for liquids.

The elastomer is preferably airtight.

The circuit boards may form a network comprising several individual circuit boards, which are located at nodes of the network and are connected to each other by the stretchable conductor paths.

In one embodiment, the network comprises several individual circuit boards and several stretchable connecting elements, each of which comprises at least one conductor path, wherein the individual circuit boards are connected to the stretchable connecting elements to form a two-dimensional grid structure.

The term “body” is to be understood in particular as a physical body or physical object.

The body preferably has a surface that is curved in two dimensions. The body is preferably an object or part of an object and not the body or a body part of a human or animal.

In one embodiment, the substrate material of the boards can be a material that is stretchable in two dimensions. In another embodiment, the substrate material is not stretchable.

The body is preferably deformable (intrinsically soft or thermoplastic).

In one embodiment, the circuit boards comprise a non-conductive carrier material on which at least one conductor path is present. The conductor path is formed from conductive material which is applied to the carrier material.

In one embodiment, the circuit boards comprise a non-conductive carrier material which can be penetrated by the precursor of the elastomer and/or the second material, which forms a different plastic. The carrier material is preferably present as a thin flat layer, for example in the form of a sheet or a strip. A penetrable carrier material is a carrier material that has openings extending from one side of the carrier material to the other. The penetrable carrier material may be a film, a fabric, a nonwoven, a fiber mat, or an open-cell foam or sponge. The material can first be produced as a dense layer and then made into a penetrable carrier material by perforation. For example, a film can be made into a penetrable carrier material by perforation. The penetrable carrier material can be made in particular from paper, fabric, glass fibers, mineral fibers, or non-conductive plastic.

Preferably, the carrier material of the circuit boards is a maximum of 2000 μm thick, particularly preferably a maximum of 500 μm, especially a maximum of 50 μm.

Preferably, the carrier material has an average pore size of at least 1 μm, particularly preferably at least 10 μm, especially at least 100 μm.

However, the circuit boards may also be non-porous.

Preferably, the circuit boards have an area in the range of 1 to 100 mm². Preferably, the maximum extension (length or diameter) of the circuit board in the plane of the surface of the body is a maximum of 10 mm. Preferably, the minimum extension (width or diameter) of the circuit board in the plane of the surface of the body is at least 0.5 mm.

Preferably, the layer thickness of the elastomer is between 0.2 and 2 mm.

Preferably, the height of the conductor paths is between 20 and 500 μm.

Preferably, the width of a conductor path is between 20 and 500 μm.

Preferably, the width occupied by several parallel conductor paths on the surface of the body is between 0.2 and 2 mm.

Preferably, the thickness of the porous body is between 1 and 100 mm.

In one embodiment, the elastomer covers only a portion of the body, wherein the elastomer is present only in an area of the surface of the body adjacent to the conductor paths and preferably in another area of the surface of the body adjacent to the circuit boards.

This ensures that the surface of the body not covered by the elastomer retains its properties. The surface of the body not covered by the elastomer can, in particular, provide a better hold for attaching a further layer compared to the elastomer.

In one embodiment, a further layer is applied over the elastomer. The further layer can, for example, be a solid and be glued to the body. The further layer can be a covering layer, in particular made of fabric or leather.

In one embodiment, the additional layer is applied while the elastomer is still liquid.

The additional layer may, for example, be a solid and be bonded to the body.

The additional layer may be porous or at least have a porous surface facing the elastomer.

In one embodiment, an additional layer applied to the elastomer before it has completely cured, in particular in the form of a porous additional layer, is fixed by the completely cured elastomer. An example of this is a foam insole as a porous body, to which a further layer in the form of a fabric covering layer is usually bonded.

### BRIEF DESCRIPTION OF THE DRAWINGS

The invention is illustrated by drawings:

FIG. 1: Schematically illustrates a first embodiment of an exemplary object.

FIG. 2: Schematically illustrates a second embodiment of an exemplary object.

FIG. 3: Schematically illustrates a third embodiment of an exemplary object.

FIG. 4: Schematically illustrates a fourth embodiment of an exemplary object.

FIG. 5: Schematically illustrates the fourth embodiment of an exemplary object in an alternative representation.

FIG. 6: Schematically illustrates a fifth embodiment of an exemplary object.

FIG. 7: Schematically illustrates a sixth embodiment of an exemplary object.

FIG. 8: Illustrates an embodiment in which a recess is adapted to the shape of the conductor paths and circuit boards.

FIG. 9: Illustrates an embodiment in which the elastomer covers only a portion of the surface.

FIG. 10: Illustrates an embodiment in which there is an additional layer above the elastomer.

### DETAILED DESCRIPTION

The embodiments shown in the figures merely illustrate possible embodiments, whereby it should be noted at this point that the invention is not limited to these specifically illustrated embodiments, but that combinations of the individual embodiments with each other and a combination of an embodiment with the above-mentioned general description are also possible. These further possible combinations do not need to be explicitly mentioned, as these further possible combinations are within the skill of a person skilled in the art based on the teaching of the present invention.

In the figures, the stretchable conductor paths 4 are shown as winding conductors, which is a preferred but not mandatory embodiment. The conductor paths 4 shown run in a winding or bent path so that the individual sections of the conductor paths 4 run transversely or not parallel to their longitudinal direction. When the length of the conductor paths 4 changes, the angle of the individual sections of the conductor paths 4 to the longitudinal direction changes, but not the cross-section and length of the conductor paths 4. This keeps the electrical resistance of the conductor paths 4 constant when the length changes.

The figures illustrate different embodiments, which have in common that they comprise a porous body 1 on which at least one circuit board 3 and at least one conductor path 4 are present, which circuit board 3 and conductor path 4 are present in an elastomer 2, which elastomer 2 was cured by casting a precursor of the elastomer in the form of a first liquid material. The liquid material penetrates into the pores of the body 1 in order to achieve good mechanical bond.

As shown, several circuit boards 3 are preferably embedded in the elastomer 2. The conductor paths 4 connect the circuit boards 3 to each other.

In addition, conductor paths 4 may be present which run from a circuit board 3 to the outside of the body 1 or the elastomer 2. The conductor paths 4 may also lead to an outer edge between the body 1 and the elastomer 2, as shown. There may also be an interface in the elastomer 2, for example in the form of a socket or a plug, which is contacted by conductor paths 4. In one embodiment, there is a socket and a plug on the object.

Central electronics (not shown) may be present in the body 1 or in the elastomer 2 or outside the body 1, which can communicate with ICs (integrated circuits) on all circuit boards 3 via the conductor paths 4. The ICs on the circuit boards 3 are preferably a combination of sensors, actuators, display elements, ADCs, DACs, analog signal processing elements, and microcontrollers, which together can perform measurement, control, and/or display functions at the position of the circuit boards 3, which are controlled or read out by the central electronics. An interface may optionally be provided on the central electronics. The interface can provide energy and/or data transmission with the central electronics. The energy and/or data transmission can be contactless, so that the interface can be completely enclosed in the body 1 and/or the elastomer 2. The interface can be in the form of a socket to enable wired energy and/or data transmission. The central electronics can comprise a rechargeable battery or another energy storage device. The central electronics can optionally be inserted into a recess in the body 1 or enclosed in the material of the body 1. The central electronics can be integrated into a body 1 manufactured by 3D printing during the printing process.

At least one electronic component 5 is arranged on the respective circuit board 3, in particular in the form of a sensor, actuator, or display element.

For the sake of simplicity, the body 1 is shown in the figures as a flat or plate-shaped element. The body 1 may have a different shape. The surface of the body 1, on which the circuit boards 3 and conductor paths 4 are located, may also have a curved profile. The circuit boards 3 may also be located on different levels of the body 1 than the conductor paths 4. Several circuit boards 3 may also be located on different levels relative to each other. Unevenness, curvatures, or a structure of the body 1 can be compensated for during casting so that the elastomer 2 forms a flat, smooth surface.

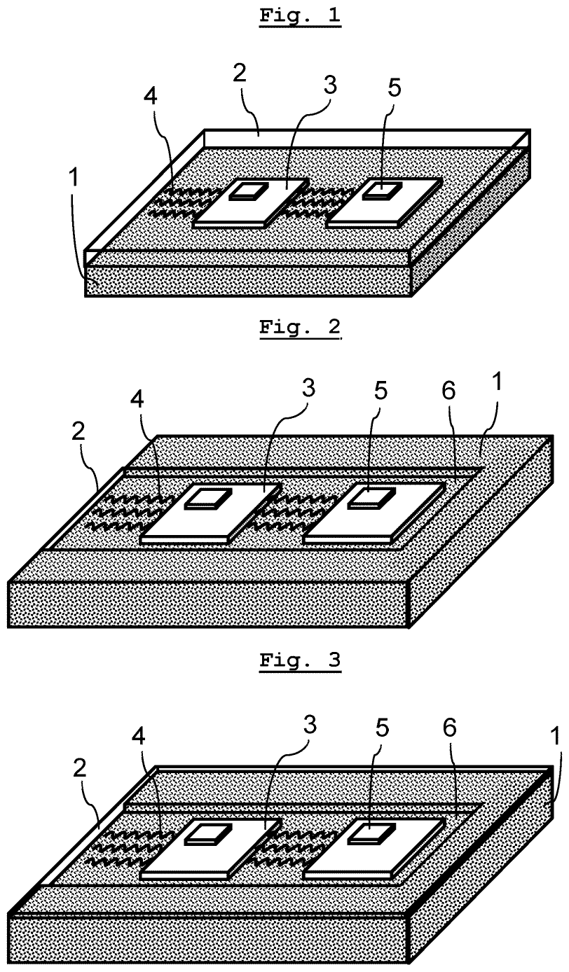

The elastomer 2 is shown transparently in FIGS. 1-4 so that the components hidden underneath are visible in the figures. The actual elastomer 2 can be transparent, translucent, or opaque.

The following describes the differences between the various embodiments.

As illustrated in FIG. 1, the circuit boards 3 and conductor paths 4 can be placed on a continuous surface of the body 1 and subsequently encapsulated by the first material, which serves to form the elastomer 2, and thereby are fixed to the body 1. The surface of the body 1, on which the circuit boards 3 and conductor paths 4 are present, is preferably completely covered by the elastomer 2. For this purpose, the body 1 can be placed in a mold and encapsulated with the elastomer.

As illustrated in FIG. 1, the circuit boards 3 and conductor paths 4 can be present in a recess 6 of the body 1. Preferably, the recess 6 is dimensionally larger than the circuit consisting of circuit boards 3 and conductor paths 4 present in the recess. Preferably, the circuit boards 3 and the conductor paths 4 have an all-around spacing from the flanks of the recess 6. In one embodiment, the flanks of the recess 6 are angled obliquely outwards and towards the center of the recess 6. The flanks of the recess 6 can also have undercuts. The flanks of the recess 6 can be porous. As illustrated in FIG. 2, the circuit boards 3 and conductor paths 4 can be placed on a continuous surface of the recess 6 of the body 1 and subsequently encapsulated by the first material, which serves to form the elastomer 2, and thereby fixed to the body 1. In FIG. 2, the elastomer 2 is limited to the area of the recess 6. The surface of the elastomer 2 is preferably flush with the surface of the body 1 surrounding the recess 6.

The embodiment of FIG. 3 differs in that the elastomer 2 covers the area of the recess 6 and the surface of the body 1 surrounding the recess.

The recess 6 is shown open on one side in FIGS. 2 and 3. However, the recess 6 can advantageously have a flank on all sides, i.e., be completely enclosed by the surface of the body 1. In this case, the recess 6 itself can serve as a casting mold.

FIGS. 4-6 illustrate the encapsulation with different materials, whereby this can of course also be carried out with embodiments having a recess 6.

At the location of at least one electronic component 5 of at least one circuit board 3, a plastic material 7 is present, which differs from the elastomer 2 by at least one property. This can be done by first encapsulating the circuit board 3, for example by placing the circuit board 3, which has not yet been placed on the body 1, in a mold or by placing a mold open on both sides on the circuit board 3 (before or after it has been placed on the body 1). Thereafter, this mold is filled with the second casting compound and, after at least partial curing, removed to form the plastic material 7. Thereafter, encapsulation with the first casting material to form the elastomer 2 can take place.

However, this can also be done by first encapsulating the elastomer 2, whereby a protective body, e.g., a mold open on both sides, is placed on the circuit board 3, which leaves a space for the second casting material. After the elastomer 2 has at least partially cured, the protective body can be removed and the remaining space can be filled with the second casting material.

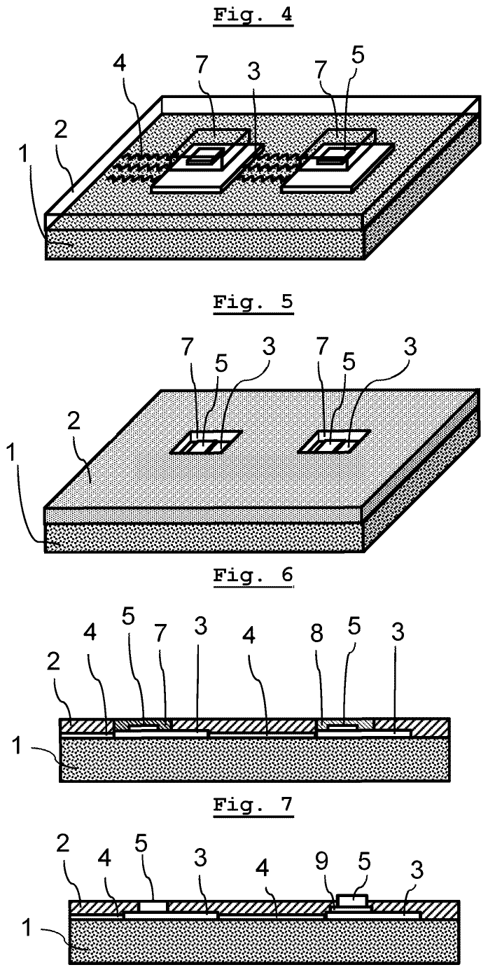

The space for the second casting material can be smaller than the area of the circuit board 3, equal to the area of the circuit board 3, or larger than the circuit board 3. The circuit board 3 can be porous or provided with at least one opening, so that the second casting compound can penetrate the circuit board 3 to connect with the underlying porous material of the body 1. In FIG. 4, the elastomer 2 and the plastic material 7 are shown transparent. In FIG. 5, the elastomer 2 is opaque and the plastic material 7 is transparent. This is preferred if the electronic components 5 are optical components.

FIG. 6 shows this embodiment in a sectional view. As shown, the circuit boards 3 and their electronic components 5 can be completely covered by the elastomer 2 and the plastic material 7. As also illustrated in FIG. 6, different second casting compounds can be used, so that a first plastic material 7 is present on a first circuit board 3 and a second plastic material 8 on another circuit board 3, which plastic materials 7, 8 differ from each other in at least one property. In addition, it is also possible for several different plastic materials 7, 8 to be present on one circuit board 3, which cover different electronic components 5. Said at least one property of the plastic material 7, 8 is preferably chosen depending on the type of electronic component 5.

FIG. 7 further illustrates an embodiment in which at least one electronic component 5 on at least one circuit board 3 is flush with the surface of the elastomer 2. For example, it is also possible, that an electrode or another electrically conductive contact surface which is flush with the surface of the elastomer 2 is present on the circuit board 3.

FIG. 7 also illustrates an embodiment in which at least one electronic component 5 on at least one circuit board 3 protrudes beyond the surface of the elastomer 2. For example, it is also possible, that an electrode or another electrically conductive contact surface which protrudes beyond the surface of the elastomer 2 is present on the circuit board 3.

An additional interface can also be arranged such that it is completely enclosed by the elastomer 2, with the connection pins, connection wires, a socket, or a plug of the interface protruding perpendicularly from the elastomer. The interface can also be in the form of a transmission coil on the surface of the body 1 and covered by the elastomer 2.

FIG. 7 also illustrates an embodiment in which an electronic component 5 or another component, which is present on a circuit board 3 and protrudes from the surface of the elastomer 2 or is flush with it, is designed with a widened area 9, which widened area 9 is covered by the elastomer 2. This allows the electronic component 5 or the other component (e.g., an interface) to also be anchored in the elastomer 2. In one embodiment, the widened area 9 is porous or provided with openings and permeable by the casting compound of the elastomer 2 and/or a plastic material 7, 8.

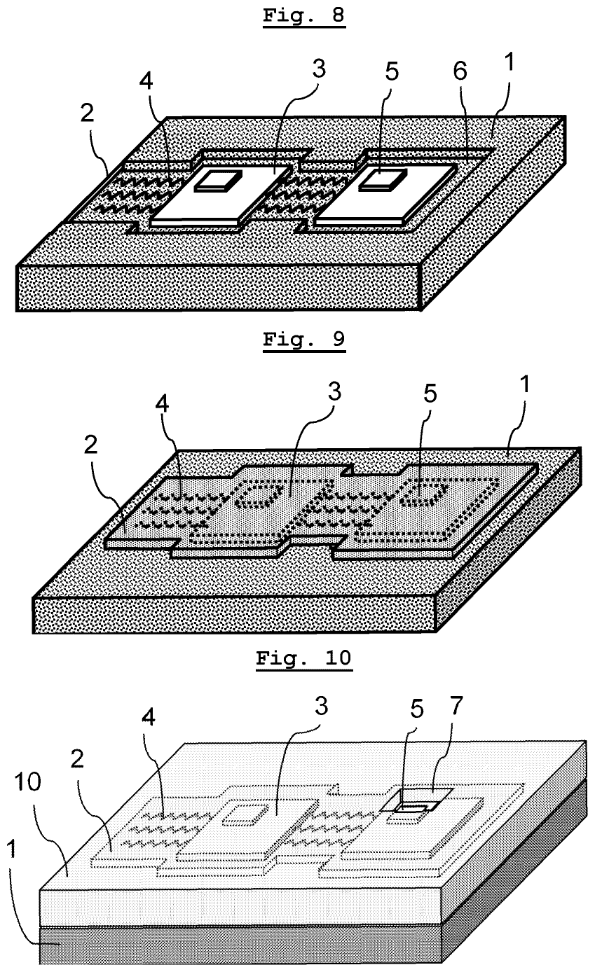

In the embodiments of FIGS. 8 and 9, the elastomer 2 covers only a partial area of the body 1, with the elastomer 2 being present only in an area of the surface of the body 1 adjacent to the conductor paths 4 and preferably a further area of the surface of the body 1 adjacent to the circuit boards 3.

In the embodiment of FIG. 8, the recess 6 is shaped according to the form of the area occupied by the conductor paths 4 and circuit boards 3. The recess 6 is preferably narrower in the area of the conductor paths 4 than in the area of the circuit boards 3. The distance of the groove flanks of the recess 6 to the conductor paths 4 and the circuit boards 3 is preferably between 0.5 and 5 mm.

In the embodiment of FIG. 9, the conductor paths 4 and circuit boards 3 are present on a continuous surface of the body 1, with only a partial area of this continuous surface being covered by the elastomer 2. This can be achieved by using a two-sided open mold with a closed circumferential wall. Preferably, the surface of the elastomer 2 is shaped according to the form of the area occupied by the conductor paths 4 and circuit boards 3. The surface of the elastomer 2 is preferably narrower in the area of the conductor paths 4 than in the area of the circuit boards 3. The distance of the edges of the elastomer 2 to the conductor paths 4 and the circuit boards 3 is preferably between 0.5 and 5 mm.

In the embodiment of FIG. 10, a further layer 10 is applied over the elastomer 2. The further layer 10 can be, for example, a solid body and can be glued to the elastomer 2 and/or the body 1. The further layer 10 can be a cover layer, particularly made of fabric or leather.

In one embodiment, the further layer 10 is applied while the elastomer is still liquid. The further layer 10 can be, for example, a solid body and can be glued to the body.

The further layer 10 can be porous, or at least have a porous surface facing the elastomer 2.

The further layer 10 can be applied in any of the embodiments of FIGS. 1 to 9. Preferably, however, this is done in one of the embodiments according to FIGS. 2, 8, or 9. In this case, the further layer 10 can be directly connected to the exposed areas of the body 1. In the embodiment of FIG. 9, the further layer 10 can have a recess in the form of the area covered by the elastomer 2.

The further layer 10 is preferably applied in the form of a solid body. Less preferably, the further layer 10 can also be applied as a hardening casting compound.

The further layer 10 can have recesses or openings in areas where electronic components 5 are present on the circuit boards 3, or can have a different material in this area than in the remaining areas of the further layer 10. A plastic material 7, 8 different from the elastomer 2 and the material of the further layer 10 can be present in an opening of the layer 10. The plastic material 7, 8 can, for example, extend through the further layer 10 and the elastomer 2, for example by pouring a hardening material, which forms the plastic material 7, 8, into a corresponding opening of the elastomer 2 and the further layer 10.

1-15. (canceled)

16. An object comprising:
a body;
wherein at least one circuit board and conductor paths connected thereto are present on at least one surface of the body;
wherein the body is deformable and at least said surface of the body is porous;
wherein the conductor paths are stretchable;
wherein at least the conductor paths are covered by an elastomer; and
wherein the elastomer extends into the pores of the surface of the body.

17. The object according to claim 16, wherein the elastomer at least partially covers the circuit board or each of several circuit boards.

18. The object according to claim 16, wherein:
the surface of the body on which the conductor paths and the at least one circuit board are present lies at a bottom of a recess of the body; and
the recess is completely filled with the elastomer.

19. The object according to claim 16, wherein the surface of the body on which the conductor paths and the circuit boards are present is completely covered with the elastomer.

20. The object according to claim 16, wherein the surface of the body on which the conductor paths and the circuit boards are present is only partially covered with the elastomer.

21. The object according to claim 20, wherein the elastomer covers the conductor paths and a partial area of the surface of the body adjacent to the conductor paths.

22. The object according to claim 16, wherein an electronic component or a contact surface is present on at least one circuit board, wherein a surface of the electronic component or the contact surface lies flush with the surface of the elastomer.

23. The object according to claim 16, wherein an electronic component is present on at least one circuit board, wherein in the area of the electronic component, instead of the elastomer, a plastic material different from the elastomer is present, which extends to the surface of the elastomer.

24. The object according to claim 16, wherein the conductor paths are present as cables or wires which have a winding, meandering or kinked course.

25. The object according to claim 16, wherein the body is stretchable and elastic.

26. A method for producing an object, the object including a body, the body being deformable and having at least one porous surface, the method comprising:
in a first step, placing at least one circuit board and stretchable conductor paths connected thereto on the porous surface of the body;
in a second step, overcasting at least the conductor paths with a first material, the first material penetrating into the pores of the surface of the body and completely covering at least the conductor paths; and
in a third step, curing the first material to form an elastomer.

27. The method according to claim 26, wherein:
in the first step, several circuit boards are placed on the porous surface of the body, which circuit boards are connected to each other at least by the stretchable conductor paths;
at least one electronic component is present on each circuit board; and
in the second step, the stretchable conductor paths are completely overcast and the circuit boards are at least partially overcast.

28. The method according to claim 26, wherein:
the surface of the body on which the conductor paths and the at least one circuit board are present lies at the bottom of a recess of the body; and
the body is already originally produced with this recess or is provided with this recess before the first step.

29. The method according to claim 26, wherein:
in addition to overcasting with the first material, overcasting with a second material takes place;
the second material takes place in the area of at least one electronic component, which is present on a circuit board; and
the second material cures to a plastic material which has different properties than the elastomer.

30. The method according to claim 26, wherein the overcasting with the first casting compound occurs to an extent such that the surface of the elastomer is flush with one or more of the following surfaces:
a surface of the body, which is raised relative to the surface of the body on which the conductor paths and the at least one circuit board are present;
a surface of a contact area, which is raised on a circuit board;
a surface of an electronic component, which is raised on a circuit board; and
a surface of a plastic material, which is formed by overcasting with a second material in the area of an electronic component on a circuit board.
